(19) United States
(12) Patent Application Publication
(10) Pub. No.: US 2019/0391213 A1
(43) Pub. Date: Dec. 26, 2019

(54) MAGNETIC FIELD MEASUREMENT SYSTEMS AND METHODS OF MAKING AND USING

(71) Applicant: HI LLC, Los Angeles, CA (US)

(72) Inventor: Jamu Alford, Simi Valley, CA (US)

(21) Appl. No.: 16/428,871

(22) Filed: May 31, 2019

Related U.S. Application Data
(60) Provisional application No. 62/689,696, filed on Jun. 25, 2018.

(51) Int. Cl. G01R 33/032; G01R 33/00; G01R 33/022

(52) U.S. Cl. CPC G01R 33/032; G01R 33/028; G01R 33/022; G01R 33/0094

(57) ABSTRACT

A magnetic field measurement system includes an array of magnetometers; at least one magnetic field generator with each of the at least one magnetic field generator configured to generate a first magnetic field at one or more of the magnetometers, wherein the generated first magnetic field combines with the ambient magnetic field to produce a directional magnetic field at the one or more of the magnetometers, where a magnitude and direction of the directional magnetic field is selectable using the at least one magnetic field generator; and a controller coupled to the magnetometers and the at least one magnetic field generator, the controller including a processor configured for receiving signals from the magnetometers, observing or measuring a magnetic field from the received signals, and controlling the at least one magnetic field generator to generate the first magnetic field and select the direction of the directional magnetic field.

### CROSS-REFERENCE TO RELATED APPLICATIONS

This application claims the benefit of U.S. Provisional Patent Application Ser. No. 62/689,696, filed Jun. 25, 2018, which is incorporated herein by reference.

### FIELD

The present disclosure is directed to the area of magnetic field measurement systems using optical magnetometers. The present disclosure is also directed to magnetic field measurement systems that modify an ambient magnetic field or target signal sources.

### BACKGROUND

In the nervous system, neurons communicate via action potentials, which transmit information through brief electric currents which flow down the length of neuron causing chemical messengers to be released at the synapse. The time-varying electrical current within the neuron generates a magnetic field. For neural signals in the brain, the magnetic field can propagate easily through the human head and can be observed. Neural and other electrical signals in other parts of the body also generate an observable magnetic field. Conventional observation and measurement devices, for example, a Superconductive Quantum Interference Device (SQUID) or an Optical Magnetometer (OM) or any other suitable magnetic field detector can be used for detection. One challenge with a SQUID detector is that it requires cryogenic cooling which can be costly and bulky.

Optical pumping magnetometers (OPM) can realize high sensitivity without requiring cryogenics. For example, the spin exchange relaxation-free (SERF) zero-field magnetometers can achieve fT/(Hz)^{1/2} sensitivity. However, conventional SERF magnetometers typically have a very narrow operating range, on the order of approximately 10-100 nT, and typically include a magnetic shield enclosure to reduce the Earth's magnetic field by a factor of approximately 500 or more. These systems can achieve very high signal-to-noise and can measure the biologically generated magnetic field due to neural activity, but the magnetic shielding can be bulky and expensive.

Scalar optical pumping magnetometers can operate in a much wider range of magnetic fields, though their sensitivity is typically limited to approximately 1 fT/(Hz)^{1/2} due to spin-exchange. Scalar magnetometers measure the magnitude of the total magnetic field by monitoring the precession frequency of a polarized ensemble of atoms. A small magnetic field of neural origin adds to other present magnetic fields. If a user were to reorient themselves in the ambient magnetic field of the earth, the contribution from the small neural signal to the quadrature sum of the earth's field and the neural signal can vary from B_{Earth}+Bₙₑᵤᵣₐₗ to B_{Earth}−Bₙₑᵤᵣₐₗ, inclusive of zero. This is may be problematic for computer algorithms employed to decode neural signals.

### BRIEF SUMMARY

One embodiment is a magnetic field measurement system including an array of magnetometers, wherein the magnetometers i) are unshielded or ii) include shielding so that an ambient magnetic field at the magnetometers is reduced no more than 90% by the shielding; at least one magnetic field generator with each of the at least one magnetic field generator configured to generate a first magnetic field at one or more of the magnetometers, wherein the generated first magnetic field combines with the ambient magnetic field to produce a directional magnetic field at the one or more of the magnetometers, wherein a direction of the directional magnetic field is selectable using the at least one magnetic field generator; and a controller coupled to the magnetometers and the at least one magnetic field generator, the controller including a processor configured for receiving signals from the magnetometers, observing or measuring a magnetic field from the received signals, and controlling the at least one magnetic field generator to generate the first magnetic field and select the direction of the directional magnetic field.

In at least some embodiments, the at least one magnetic field generator is a single magnetic field generator configured to generate the first magnetic field at each of the magnetometers. In at least some embodiments, the at least one magnetic field generator includes a plurality of magnetic field generators. In at least some embodiments, the at least one magnetic field generator includes a plurality of magnetic field generators with each magnetic field generator, disposed around, and generating the first magnetic field for, a different one of the magnetometers.

In at least some embodiments, each of one or more pairs of the magnetometers are arranged as a gradiometer. In at least some embodiments, the at least one magnetic field generator includes a plurality of magnetic field generators with each magnetic field generator, disposed around, and generating the first magnetic field for, a different one of the magnetometers or gradiometers.

In at least some embodiments, the magnetic field measurement system further includes at least one magnetic field sensor configured for observing the ambient magnetic field, wherein the processor of the controller is coupled to the at least one magnetic field sensor and configured to alter the first magnetic field generated by the at least one magnetic field generator in response to a change in the measured ambient magnetic field. In at least some embodiments, the magnetic field measurement system further includes at least one position or orientation sensor associated with the magnetometers for sensing changes in position or orientation of the magnetometers, wherein the processor of the controller is coupled to the at least one position or orientation sensor and to alter the first magnetic field generated by the at least one magnetic field generator in response to a change in the position or orientation of the magnetometers.

Another embodiment is a method of measuring or observing a signal source using any of the magnetic field measurement systems described above. The method includes positioning the array of magnetometers in relation to the signal source; generating, using the at least one magnetic field generator, the first magnetic field at the magnetometers; and observing or measuring a magnetic field produced by the signal source using the magnetometers.

In at least some embodiments, the method further includes obtaining an estimate of a direction of the magnetic field produced by the signal source (for example, a current generated in the brain or other region of the body) and selecting the first magnetic field to produce the directional magnetic field at the magnetometers in a direction that is within 20 degrees of parallel or antiparallel to the direction of the magnetic field produced by the signal source. In at least some embodiments, the magnetic field measurement system includes a sensor selected from a magnetic field sensor, a position sensor, or an orientation sensor, the method further including adjusting the first magnetic field is response to the sensor.

Yet another embodiment is a method of targeted observation or measurement of a source of electromagnetic signals. The method includes obtaining an estimate of a direction of a source magnetic field generated by a signal source, wherein the signal source is disposed at a site; positioning an array of magnetometers in relation to the site of the signal source; generating a directional magnetic field in a direction that is within 20 degrees of parallel or antiparallel to the direction of the source magnetic field at each of a plurality of the magnetometers in the array; and analyzing signals generated at the plurality of the magnetometers to observe or measure the source magnetic field generated by the signal source.

In at least some embodiments, the plurality of magnetometers includes at least one pair of the magnetometers arranged as a gradiometer. In at least some embodiments, generating the directional field includes using at least one magnetic field generator to generate at least one first magnetic field, wherein the at least one first magnetic field combines with an ambient magnetic field to produce the directional magnetic field at each of the magnetometers, wherein a direction of the directional magnetic field is selectable using the at least one magnetic field generator.

In at least some embodiments, the method further includes receiving signals from a magnetic field sensor observing the ambient magnetic field and adjusting the at least one first magnetic field in response to the signals from the magnetic field sensor. In at least some embodiments, the method further includes receiving signals from a position or orientation sensor observing a position or orientation of the magnetometers and adjusting the at least one first magnetic field in response to the signals from the position or orientation sensor.

A further embodiment is a magnetic field measurement system including an array of magnetometers; and a controller coupled to the magnetometers, the controller including a processor configured to: obtain an estimate of a direction of a source magnetic field generated by a signal source, wherein the signal source is disposed at a site; generate a directional magnetic field in a direction that is within 20 degrees of parallel or antiparallel to the direction of the source magnetic field at each of a plurality of the magnetometers arranged in the array and positioned in relation to the site of the signal source; and analyze signals generated at each of the magnetometers to observe or measure the source magnetic field generated by the signal source.

In at least some embodiments, the magnetic field measurement system further includes at least one magnetic field generator coupled to the controller, wherein the processor is further configured to, for each of the at least one magnetic field generator, generate a first magnetic field at one or more of the magnetometers, wherein the first magnetic field combines with an ambient magnetic field to produce the directional magnetic field at the one or more of the magnetometers, wherein the direction of the directional magnetic field is selectable using the at least one magnetic field generator.

In at least some embodiments, the magnetic field measurement system further includes a sensor selected from a magnetic field sensor, a position sensor, or an orientation sensor, wherein the processor is further configured to adjust the first magnetic field in response to the sensor. In at least some embodiments, the magnetometers i) are unshielded or ii) include shielding so that an ambient magnetic field at the magnetometers is reduced no more than 90% by the shielding.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified.

For a better understanding of the present invention, reference will be made to the following Detailed Description, which is to be read in association with the accompanying drawings, wherein:

FIG. 1 is a schematic block diagram of one embodiment of a magnetic field measurement system, according to the invention;

FIG. 2 is a schematic side view of one embodiment of an array of magnetometers for measuring magnetic fields generated in a brain of a user, according to the invention;

FIG. 3 is a schematic side view of one embodiment of the array of magnetometers of FIG. 2, a signal source in a brain of a user, and a direction of the ambient magnetic field, according to the invention;

FIG. 4 illustrates addition of magnetic field vectors that are parallel or perpendicular to the ambient magnetic field, according to the invention;

FIG. 5A is a schematic side view of one embodiment of an array of magnetometers and a magnetic field generator for measuring magnetic fields generated in a brain of a user, according to the invention;

FIG. 5B illustrates aspects of one embodiment of a magnetic field generator in the form of a tri-axis Helmholtz coil electromagnet system, according to the invention;

FIG. 5C illustrates the addition of a generated magnetic field to the ambient magnetic field to produce a directional magnetic field, according to the invention;

FIG. 6A is a schematic side view of another embodiment of an array of magnetometers for measuring magnetic fields generated in a brain of a user with directional fields parallel to the magnetic field generated by a signal source, according to the invention;

FIG. 6B is a schematic side view of another embodiment of an array of magnetometers for measuring magnetic fields generated in a brain of a user with directional fields perpendicular to the magnetic field generated by a signal source, according to the invention;

FIG. 7 is a schematic side view of one embodiment of a magnetometer with an individual magnetic field generator, according to the invention;

FIG. 8 is a graph of drive current versus time for a magnetic field generator, according to the invention;

FIG. 9A is a schematic side view of another embodiment of two magnetometers, arranged as a gradiometer, and a magnetic field generator, according to the invention;

FIG. 9B illustrates aspects of the magnetic field generator of FIG. 9A in the form of two interconnected tri-axis Helmholtz coil electromagnet systems, according to the invention;

FIG. 10 is a flow diagram of one embodiment of a method of observing or measuring a magnetic field generated by a signal source, according to the invention; and

FIG. 11 is a flow diagram of another embodiment of a method of observing or measuring a magnetic field generated by a signal source, according to the invention.

### DETAILED DESCRIPTION

The present disclosure is directed to the area of magnetic field measurement systems using optical magnetometers. The present disclosure is also directed to magnetic field measurement systems that modify an ambient magnetic field or target signal sources.

In at least some embodiments, the magnetic environments around the magnetometer(s) are controlled in order to capture the biological magnetic signals, independent of the orientation of the user in the earth's field and allow selective detection from specific neural signals by adjusting the magnetic field direction at individual sensors.

Optical magnetometry is the use of optical methods to measure a magnetic field. In at least some cases, the magnetic field can be measured with accuracy on the order of 1×10¹⁵ Tesla. A vector optical magnetometer can be used to determine the magnetic field components along one, two or three Cartesian axes, but typically includes substantial shielding to reduce the background (e.g., ambient) magnetic field by a factor of, for example, 500 or more. This shielding can be bulky and costly.

Scalar optical magnetometers typically measure the magnitude of the magnetic field, not the directionality. Recently, scalar magnetometers have been developed that can achieve high-sensitivity in ambient magnetic fields close to the strength of the Earth field. However, in many instances, the scalar optical magnetometers also utilize shielding. Shielding can include passive shielding (for example, paramagnetic materials) and active shielding (for example, an electromagnet or permanent magnet that counteracts the background magnetic field). If not shielded (often using at least passive shielding), scalar optical magnetometers primarily measure a portion of the magnetic field that is aligned along the same axis as the background or ambient magnetic field (either parallel or antiparallel).

A magnetic field measurement system, as described herein, can include an array of magnetometers including, for example, scalar optical magnetometers (also referred to herein as “scalar magnetometers”.) The magnetic field measurement system can be used to measure or observe electromagnetic signals generated by one or more sources (for example, biological sources). The magnetometers can measure biologically generated magnetic fields and, at least in some embodiments, can measure biologically generated magnetic fields that are not aligned with the background or ambient magnetic field and, at least in some embodiments, without shielding or with substantially less shielding than conventional arrangements. The systems and methods described herein can be used to observe and measure signals from the brain or from other areas of the body. In addition, such systems and methods can also be useful for observation or measurement of non-biological signals and magnetic fields.

In some embodiments, two magnetometers may be combined to form a gradiometer (e.g., by taking the difference between the two magnetometers) to observe or measure only the spatial variability (e.g., the gradient) of the magnetic field. Such an arrangement may dramatically reduce the effect of the ambient or background magnetic field, which is often invariant (or nearly invariant) in space and therefore has a low spatial gradient. First order gradients subtract two signals and measure the ‘slope’ of the field. An arrays of N magnetometers can be used to measure higher order magnetic field gradients in multiple dimensions.

Herein the terms “ambient magnetic field” and “background magnetic field” are interchangeable and used to identify the magnetic field or fields associated with sources other than the magnetic field measurement system and the biological source(s) (for example, neural signals from a user's brain) or other source(s) of interest. The terms can include, for example, the Earth's magnetic field, as well as magnetic fields from magnets, electromagnets, electrical devices, and other signal or field generators in the environment, except for the magnetic field generator(s) that are part of the magnetic field measurement system.

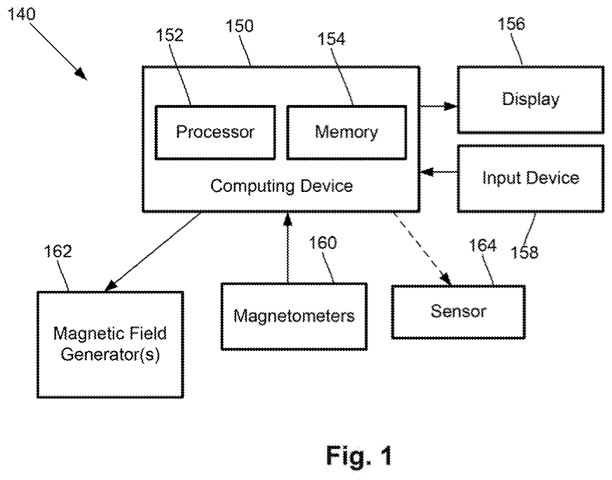

FIG. 1 is a block diagram of components of one embodiment of a magnetic field measurement system 140. The system 140 can include a computing device 150 or any other similar device that includes a processor 152 and a memory 154, a display 156, an input device 158, an array of magnetometers 160, one or more magnetic field generators 162, and, optionally, one or more sensors 164. The system 140 and its use and operation will be described herein with respect to the measurement of neural signals arising from signal sources in the brain as an example. It will be understood, however, that the system can be adapted and used to measure other neural signals, other biological signals, as well as non-biological signals.

The computing device 150 can be a computer, tablet, mobile device, or any other suitable device for processing information. The computing device 150 can be local to the user or can include components that are non-local to the user including one or both of the processor 152 or memory 154 (or portions thereof). For example, in at least some embodiments, the user may operate a terminal that is connected to a non-local computing device. In other embodiments, the memory 154 can be non-local to the user.

The computing device 150 can utilize any suitable processor 152 including one or more hardware processors that may be local to the user or non-local to the user or other components of the computing device. The processor 152 is configured to execute instructions provided to the processor 152, as described below.

Any suitable memory 154 can be used for the computing device 152. The memory 154 illustrates a type of computer-readable media, namely computer-readable storage media. Computer-readable storage media may include, but is not limited to, nonvolatile, non-transitory, removable, and non-removable media implemented in any method or technology for storage of information, such as computer readable instructions, data structures, program modules, or other data. Examples of computer-readable storage media include RAM, ROM, EEPROM, flash memory, or other memory technology, CD-ROM, digital versatile disks (“DVD”) or other optical storage, magnetic cassettes, magnetic tape, magnetic disk storage or other magnetic storage devices, or any other medium which can be used to store the desired information and which can be accessed by a computing device.

Communication methods provide another type of computer readable media; namely communication media. Communication media typically embodies computer-readable instructions, data structures, program modules, or other data in a modulated data signal such as a carrier wave, data signal, or other transport mechanism and include any information delivery media. The terms “modulated data signal,” and “carrier-wave signal” includes a signal that has one or more of its characteristics set or changed in such a manner as to encode information, instructions, data, and the like, in the signal. By way of example, communication media includes wired media such as twisted pair, coaxial cable, fiber optics, wave guides, and other wired media and wireless media such as acoustic, RF, infrared, and other wireless media.

The display 156 can be any suitable display device, such as a monitor, screen, display, or the like, and can include a printer. In some embodiments, the display is optional. In some embodiments, the display 156 may be integrated into a single unit with the computing device 150, such as a tablet, smart phone, or smart watch. The input device 158 can be, for example, a keyboard, mouse, touch screen, track ball, joystick, voice recognition system, or any combination thereof, or the like.

The magnetometers 160 can be any suitable magnetometers including any suitable scalar optical magnetometers. The magnetic field generator(s) 162 can be, for example, Helmholtz coils, solenoid coils, planar coils, saddle coils, electromagnets, permanent magnets, or any other suitable arrangement for generating a magnetic field. The optional sensor(s) 164 can include, but are not limited to, one or more magnetic field sensors, position sensors, orientation sensors, or the like or any combination thereof.

When measuring a weak magnetic field (such as a magnetic field generated by a biological process), which is superimposed on top of a strong background magnetic field, such as the Earth's magnetic field (or the ambient or background magnetic field that includes the Earth's field), only the component of the weak magnetic field that is parallel (or anti-parallel) with the strong background magnetic field can be detected with a scalar magnetometer. If the background magnetic field is oriented perpendicular to the weak magnetic field, which the user wants to measure or observe, the weak magnetic field will often not be detected. If the weak magnetic field changes angle dynamically, with respect to the background magnetic field (for example, attempting to measure the magnetic fields generated by the body of a person who is moving), the measured value will continuously change as different biological magnetic field vectors align and misalign with the background magnetic field.

However, if the background magnetic field is modified to produce a directional magnetic field oriented in a particular direction (for example, aligned with a magnetic field generated by a biological signal), then a scalar magnetometer can have improved sensitivity to the signal of interest. In some embodiments, this arrangement may also be used to select signals from a particular location and direction, while reducing sensitivity to other signals. This can allow dynamic focused sensing of particular regions of the brain or flows of electrical current within a region when multiple magnetometers are used and each magnetometer is configured to measure in such a way to select a signal from a specific source.

Because the magnetic field generated by the brain is a vector (with direction and amplitude) and the much stronger background or ambient magnetic field is also a vector, they add as a vector sum. When a scalar magnetometer is used to measure the total field, only magnetic fields (or the portions of the magnetic fields) that are parallel or antiparallel to the much larger background or ambient magnetic field are measured. As an example, half of all measured neural signals generated by the brain may be reduced more than 50% because of the background or ambient magnetic field.

It has been found that the use of a generated, dynamically controlled directional magnetic field (for example, formed as a combination of the ambient magnetic field and a magnetic field produced by the system) can facilitate measurement of neuronal or other signals with a magnetometer, such as a scalar optical magnetometer. In at least some embodiments, specific neuronal or other signals with a certain location and angle can be targeted using the system. In at least some embodiments, signals from other regions can be suppressed.

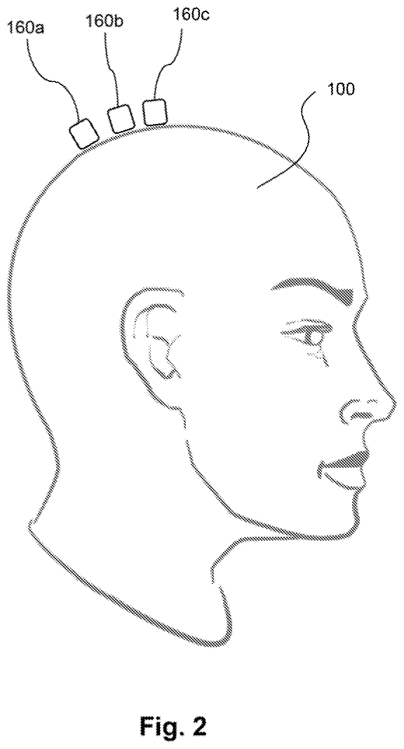

FIG. 2 illustrates multiple scalar magnetometers, 160a, 160b, 160c positioned on (or over or above) a user's head 100 to observe and measure neural activity. It will be understood that a magnetic field measurement system can include any number of magnetometers including, but not limited to, one, two, four, eight, ten, sixteen, twenty, thirty, thirty-two, fifty, sixty-four, one hundred, or more magnetometers. The illustrated magnetometers are also arranged as an array in a single plane, but it will be recognized that the magnetometers of a magnetic field measurement system can be arranged as an array in any other two- or three-dimensional arrangements to cover all or a portion of the individual's cranium or head. In some embodiments, the magnetometers of a magnetic field measurement system may be provided in a housing, casing, cap, or other rigid or flexible article or in any combination of such articles.

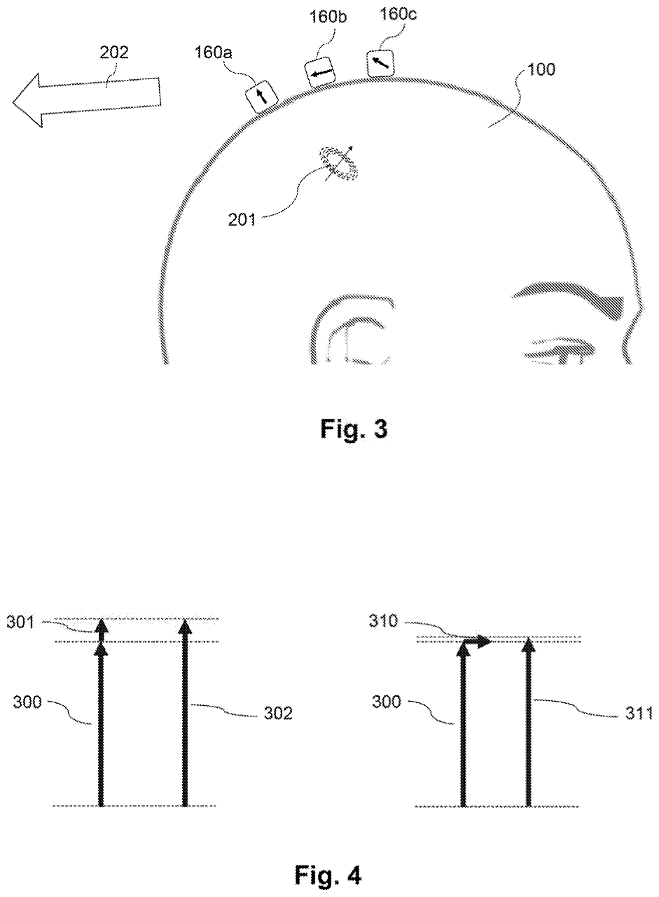

FIG. 3 illustrates the vector magnetic fields in the individual magnetometers 160a, 160b, 160c that might be generated by neural activity at site 201. The magnetic vectors at each of the magnetometers 160a, 160b, 160c, could be different in both direction and amplitude based, at least in part, on the position of the magnetometer relative to the neural activity. The ambient magnetic field (for example, the background magnetic field of the Earth) is represented by the vector 202 and is about 10⁹ times larger than the signal from the neural activity at site 201 and is not shown to scale. In the example illustrated in FIG. 3, the vector magnetic field at magnetometer 160a, from the neural activity at site 201 is perpendicular to the ambient magnetic field 202 and likely cannot be measured at all. In contrast, the vector magnetic field at magnetometer 160b from the neural activity at site 201 is parallel to the ambient magnetic field 202 and can be measured fully. The vector magnetic field at the third magnetometer 160c from the neural activity at site 201 is at 45 degrees to the background field so can be measured at approximately 70% of its actual amplitude.

FIG. 4 demonstrates visually how a background vector 300 and a neural signal vector 301 add linearly when parallel to form a composite vector 302, but a perpendicular neural vector 310 adds in quadrature using the Pythagorean Theorem (a²+b²=c²) to generate a composite vector 311. Since background vector 300 and composite vector 311 are the same length no signal change is measured due to the perpendicular neural signal.

Because the biological signals are already very small and difficult to detect it is useful to create a situation in which the biological magnetic field is parallel or antiparallel (or no more than 5, 10, 15, 20, or 30 degrees from parallel or antiparallel) to the ambient magnetic field for a biological signal or signals of interest to be detected, measured, or observed. In at least some embodiments, it may also be possible to position the biological magnetic field perpendicular (or at least 45, 60, 70, 80, or more degrees from parallel or antiparallel) to the ambient magnetic field for the biological signal or signals that are not of interest or not to be measured or detected.

In some embodiments, a magnetometer may be placed at some distance from the head (or other signal source or the other magnetometers) to sample the ambient magnetic field rather than a vector sum of both the biological magnetic field and ambient magnetic field. In at least some of these embodiments, this magnetometer may act as a magnetic field sensor as described below.

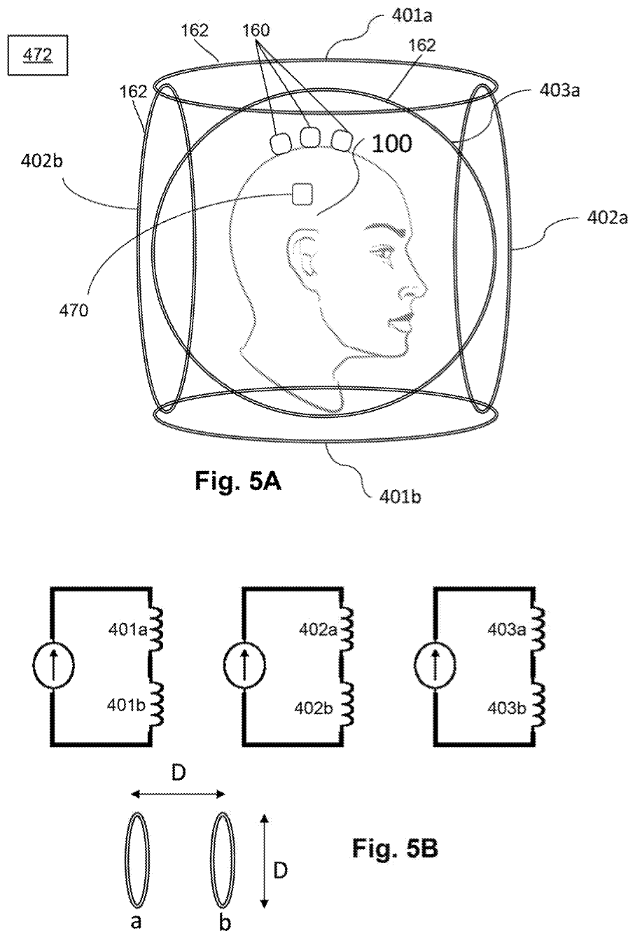

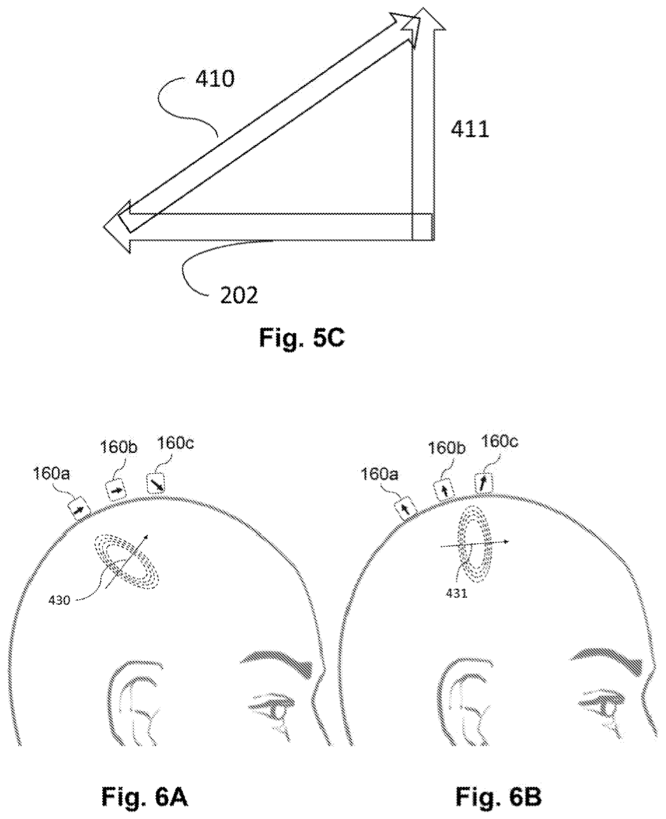

In at least some embodiments, to modify or control the direction of the ambient magnetic field a magnetic field generator 162 is positioned near or around one or more magnetometers 160, as illustrated in FIG. 5A. Any suitable magnetic field generator 162 can be used including, but not limited to, one or more Helmholtz coils, solenoid coils, planar coils, saddle coils, other electromagnets, or permanent magnets or any combination thereof.

In FIG. 5A, the magnetic field generator is a tri-axis Helmholtz coil electromagnet system with coils 401a, 401b, 402a, 402b, 403a, 403b (not shown). As illustrated in FIG. 5B, one embodiment of a Helmholtz coil includes two magnetic loops of diameter D that are separated by distance D to generate a uniform magnetic field along the center line that connects the two constituent coils (labeled “a” and “b”.) To generate a 3-dimensional magnetic vector of arbitrary choosing, three sets of

Helmholtz coils are used to form a tri-axis Helmholtz coil electromagnet system. The vertical Helmholtz coils 401a, 401b generate the vertical component of the magnetic field, Helmholtz coils 402a, 402b generate the front-back vector component and Helmholtz coils 403a, 403b (coil 403b is not shown in FIG. 5A) generate the left-right vector component, as illustrated in FIGS. 5A and 5B. In at least some embodiments, the tri-axis Helmholtz coil electromagnet system is large compared to the human head so that the non-linear fields generated close to the coils are relatively far from the magnetometers.

In at least some embodiments and in contrast to many conventional magnetometer arrangements, the magnetometers 160 are either: i) not shielded, or ii) shielded to reduce the ambient magnetic field no more than 10, 20, 25, 30, 40, 50, 75, or 90%. Such embodiments avoid or reduce the amount of bulky and costly shielding (for example, passive shielding or large electromagnets to suppress the ambient magnetic field/magnetic field gradients or any combination thereof) present in many conventional systems. Instead of reducing the ambient magnetic field to a relatively small field by shielding as in many conventional magnetometer arrangements, in these embodiments of the magnetic field measurement system, the magnetic field generator 162 generates a magnetic field that combines with the ambient magnetic field to create a directional magnetic field aligned in a desired direction. In at least some embodiments, the generated magnetic field is within an order of magnitude of the ambient magnetic field (e.g., within a range of 0.1 times to 10 times the ambient magnetic field.) In at least some embodiments, if shielding is used, the generated magnetic field is within an order of magnitude of the reduced ambient magnetic field (e.g., within a range of 0.1 times to 10 times the reduced ambient magnetic field.) In at least some embodiments, the generated magnetic field is within a range of 0.5 to 5 times the ambient magnetic field or reduced ambient magnetic field.

FIG. 5C illustrates how the ambient magnetic field 202, and the magnetic field 410 generated by the magnetic field generator 162, result in directional magnetic field 411 in the desired direction. The direction of directional magnetic field 411 can be directed along any vector to measure a specific neural or other signal. By changing the direction of the magnetic field 410 generated by the magnetic field generator, the direction of the directional magnetic field can also be changed. In at least some embodiments, as described below, a magnetic field sensor may detect changes in the ambient magnetic field 202 and alter the magnetic field 410 to dynamically reduce variation in the directional magnetic field 411.

The embodiment illustrated in FIG. 5A uses a single modification field for all of the magnetometers. In some embodiments, there may be little or no ability to individually control the ambient magnetic field at the scale of the individual magnetometers.

In other embodiments, a separate magnetic field generator 162 is provided for each magnetometer 160 or for each subset of magnetometers (for example, for a subset of two magnetometers forming a gradiometer as described below). In FIG. 6A, a neural signal in the brain at site 430 generates signal magnetic vectors at the magnetometers 160a, 160b and 160c. A neural signal at site 431 in FIG. 6B produces different magnetic vectors at magnetometers 160a, 160b and 160c. If the ambient magnetic field is controlled in such a way that at each magnetometer position it was directed to be parallel or antiparallel (or at least less than 5, 10, 15, 20, or 30 degrees from parallel or antiparallel) to the vectors in FIG. 6A, the result would be a magnetic field measurement system would be sensitive to magnetic fields from site 430. In at least some embodiments, the magnetic field measurement system may be less sensitive or insensitive to magnetic fields generated at site 431 which are perpendicular to the magnetic fields generated at site 430.

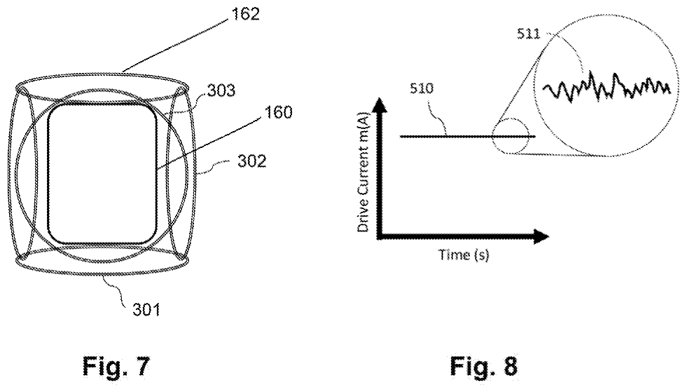

In FIG. 7, a magnetic field generator 162 (such as a tri-axis Helmholtz coil electromagnet system 301, 302, 303) is positioned (for example, wound) around a single magnetometer 160. The array of magnetometers 160 of the magnetic field measurement system 140 can each have a separate magnetic field generator 162. In other embodiments, each subset of magnetometers (for example, two, three, four, or more magnetometers) may have a separate magnetic field generator 162. This permits more local control of the magnetic field than the arrangement illustrated in FIG. 5A.

FIG. 8 illustrates that electronic noise 511 on the drive current from the power supply 510 that powers the Helmholtz coils is a possible source of system noise. It is preferable that the current source generates low noise.

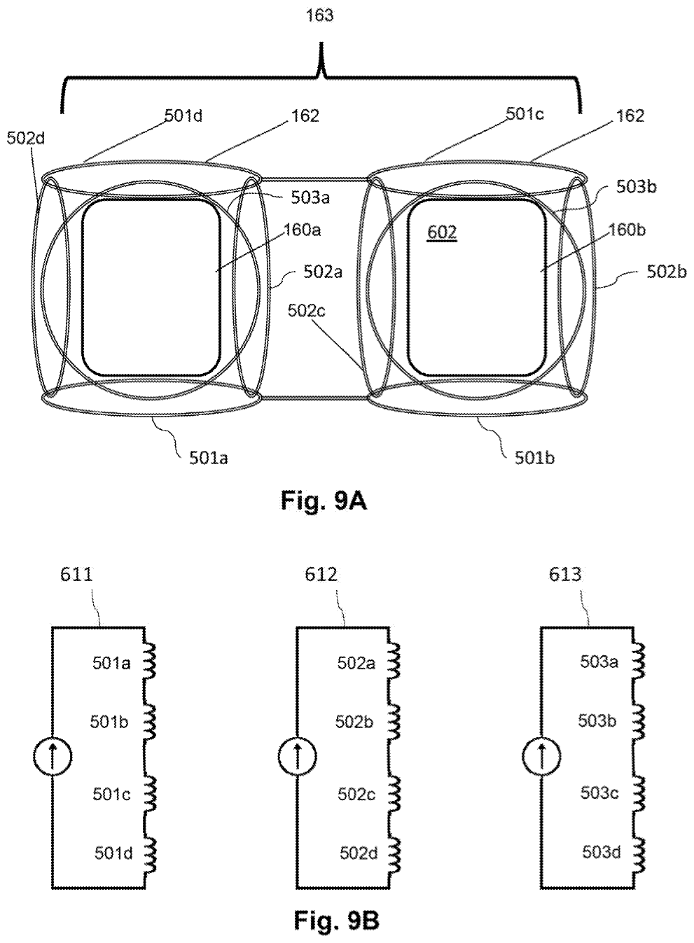

In FIG. 9A, two magnetometers 160a, 160b are combined to create a gradiometer 163 with a magnetic field generator 162 disposed around the magnetometers. A gradiometer only detects magnetic fields that differ between the two magnetometers through subtraction of the common mode signals of the two magnetometers. Magnetic fields that don't possess a spatial variability over the separation distance, like the Earth's magnetic field, will be canceled as will common mode noise. The magnetic field generator 162 includes two tri-axis Helmholtz coils 501a-d, 502a-d, 503a-d (503c and 503d not shown) placed around the two magnetometers. FIG. 9B shows how the two tri-axis Helmholtz coils 501a-d, 502a-d, 503a-d are wired in series so that any current instabilities (for example, noise) 511 (FIG. 8) are the same for each of the magnetometers 160a, 160b. Since the current instabilities are common for each of the magnetometers 160a, 160b they are subtracted away as common-mode noise.

Returning to FIG. 1, the magnetic field measurement system 140 can include one or more optional sensors 164. As an example, a position or orientation sensor 470 (FIG. 5A), for example, one or more accelerometers, gyroscopes, or any other suitable position or orientation detectors or any combination thereof, can be positioned near the array of magnetometers 160. This position or orientation sensor 470 can be used to, for example, track the user's motion; particularly, the user's motion relative to the ambient magnetic field. As the user moves, the orientation of the magnetometers 160 relative to the ambient magnetic field can change. In at least some embodiments, the processor 152 of the computing device 150 can adjust the magnetic field(s) generated by the magnetic field generator(s) in view of a change in position or orientation as detected by the position or orientation sensor 470.

Another optional sensor is a magnetic field sensor 472 (FIG. 4A), such as one or more three-axis Hall probes, three-axis flux gates, three-axis GMR sensor, or any other suitable magnetic field detectors or any combination thereof, to measure the amplitude or direction (or both) of the ambient magnetic field. There can be changes in the ambient magnetic field due to a variety of factors such as, for example, electrical devices being turned on or off or otherwise altering their magnetic field during operation, changing density of radiofrequency and other signals in the area near the magnetometers, and the like. In at least some embodiments, the processor 152 of the computing device 150 can adjust the field(s) generated by the magnetic field generator(s) in view of a change in the ambient magnetic field as detected by the magnetic field sensor 472.

A magnetic field measurement system 140 (FIG. 1) can include one or more position or orientation sensors 470, one or more magnetic field sensors 472, or any combination thereof.

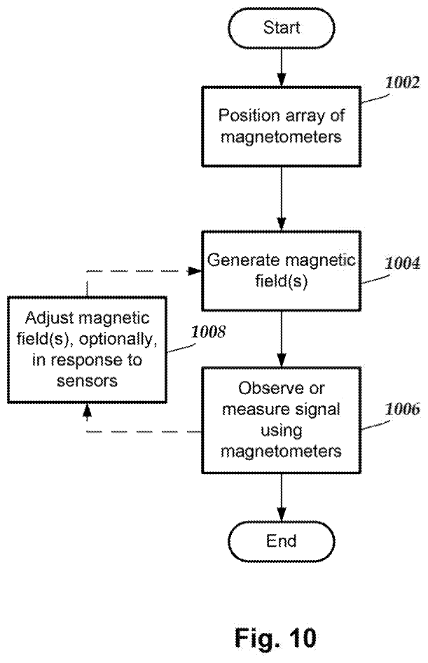

FIG. 10 illustrates one embodiment of a method of measuring or observing a signal source, such as a biological signal source, that produces a magnetic field. In step 1002, an array of magnetometers 162 of a magnetic field measurement system 140 is positioned for observing or measuring the signal source. In step 1004, one or more magnetic fields are generated using the magnetic field generator(s) 164 to produce a directional magnetic field at each of the magnetometers in a selected direction. The directions at the individual magnetometers 162 can be the same or different. The processor 152 of the computing device 150 can be used to determine or receive the selected direction for the magnetometers 160 and direct the magnetic field generator(s) 162 to produce the corresponding magnetic field(s) which, when combined with the ambient magnetic field, produce the directional magnetic fields at the magnetometers.

In some embodiments, the direction(s) of the directional magnetic fields can be selected by the system 140 or a user.

In at least some embodiments, the system 140 or a user may provide an estimate of the direction of the magnetic field produced by the signal source to be measured. This estimate can be used to determine or select a direction for the directional magnetic fields at one or more of the magnetometers 160. For example, the direction may be selected to be parallel or antiparallel (or no more than 5, 10, 15, 20, or 30 degrees from parallel or antiparallel) with respect to the estimated direction of the magnetic field to be measured.

In step 1006, the signal source is observed or measured using the magnetometers 160. In at least some embodiments, the magnetometers 160 produce signals corresponding to the magnetic fields detected at the magnetometers 160 and those signals are provided to the processor 152 of the computing device 150 for observing the magnetic fields (or changes in the magnetic fields) or for calculating, estimating, or otherwise determining the size of the magnetic field arising from the observed signal source, for example, a biological signal source. The results of the observation or measurement can be stored and presented to a user on the display or in any other format 156. The observation or measurement of the signal source using the magnetometers can be repeated multiple times.

In optional step 1008, the magnetic field(s) generated by the magnetic field generator(s) can be altered to generate a new set of magnetic field(s) in step 1004. In some embodiments, the alteration to the magnetic field(s) may be made to observe a different signal source, for example, a different biological signal source.

In some embodiments, the alteration to the magnetic field(s) may be made in response to a position or orientation sensor 470 (FIG. 5A) which detects a change in a position or orientation of the user or other object being observed. (It will also be recognized that movement may also result in an alteration of the magnetic field due to differences, for example, in nearby magnetic field sources or the presence of other materials, such as metal beams or the like. Such changes may be detected using the magnetic field sensor 472 described below). The change in position or orientation may change the orientation of the magnetometers 162 with respect to the ambient magnetic field resulting in an alteration of the direction of the directional magnetic fields at the magnetometers. The alteration in step 1008 may return the direction of the directional magnetic field back to the previous direction (or may produce a different direction.)

In some embodiments, the alteration to the magnetic field(s) may be made in response to a magnetic field sensor 472 (FIG. 5A) which detects a change in the ambient magnetic field. The change in the ambient magnetic field may alter the direction of the directional magnetic fields at the magnetometers 160. The alternation in step 1008 may return the direction of the directional magnetic field back to the previous direction (or may produce a different direction.)

It will be recognized that a magnetic field measurement system 140 may be configured to adjust the magnetic field(s) for any one of these reasons or any combination of these reasons.

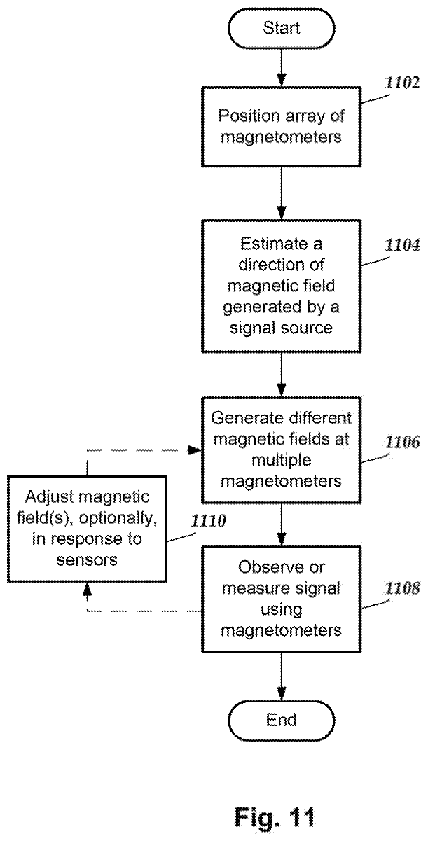

FIG. 11 illustrates one embodiment of a method of measuring or observing a signal source, such as a biological signal source, that produces a magnetic field where the signal source is selected and preferentially observed. In step 1002, an array of magnetometers 162 of a magnetic field measurement system 140 is positioned for observing or measuring the signal source. In step 1104, the system 140 or a user may provide an estimate of the direction of the magnetic field produced by the signal source to be measured. In step 1106, one or more magnetic fields are generated using the magnetic field generators 164 to produce a directional magnetic field at each of the magnetometers in a selected direction. The directions at the individual magnetometers 162 can be the same or different. The estimate of the direction of the magnetic field generated by the signal source can be used to determine or select a direction for the directional magnetic fields at one or more of the magnetometers 160. For example, the direction may be selected to be parallel or antiparallel (or no more than 5, 10, 15, 20, or 30 degrees from parallel or antiparallel) with respect to the estimated direction of the magnetic field of the signal source to be measured. In at least some embodiments, the directional magnetic fields at different magnetometers (or different subsets of magnetometers, such as two magnetometers coupled together to form a gradiometer) will be different because the magnetometers are positioned differently with respect to the magnetic field orientation of the signal source. On the other hand, the directional magnetic fields at the magnetometers are not necessarily aligned parallel or antiparallel (or no more than 5, 10, 15, 20, or 30 degrees from parallel or antiparallel) with respect to the magnetic fields of other signal sources.

The processor 152 of the computing device 150 can be used to determine or receive the selected direction(s) for the magnetometers 160 and direct the magnetic field generator(s) 162 to produce the corresponding magnetic field(s) which, when combined with the ambient magnetic field, produce the directional magnetic fields at the magnetometers. In some embodiments, the direction of the directional magnetic fields can be selected by the system 140 or a user.

In step 1108, the signal source is observed or measured using the magnetometers 160. In at least some embodiments, the magnetometers 160 produce signals corresponding to the magnetic fields detected at the magnetometers 160 and those signals are provided to the processor 152 of the computing device 150 for observing the magnetic fields (or changes in the magnetic fields) or for calculating, estimating, or otherwise determining the size of the magnetic field arising from the observed signal source, for example, a biological signal source. The results of the observation or measurement can be presented to a user on the display or in any other format 156. The observation or measurement of the signal source using the magnetometers can be repeated multiple times.

In at least some embodiments, observation of a magnetic field at all of at least a threshold percentage (for example, at least 75, 80, or 90%) of the magnetometers will indicate that the magnetic field arises from the target signal source. Observation of a magnetic field is fewer of the magnetometers may be due to other signal sources.

In optional step 1110, the magnetic field(s) generated by the magnetic field generator(s) can be altered to generate a new set of magnetic field(s) in step 1006. In some embodiments, the alteration to the magnetic field(s) may be made to observe a different signal source, for example, a different biological signal source.

In some embodiments, the alteration to the magnetic field(s) may be made in response to a position or orientation sensor 470 (FIG. 5A) which detects a change in a position or orientation of the user or other object being observed. The change in position or orientation may change the orientation of the magnetometers 162 with respect to the ambient magnetic field resulting in an alteration of the direction of the directional magnetic fields at the magnetometers. The alteration in step 1110 may return the direction of the directional magnetic field back to the previous direction (or may produce a different direction.)

In some embodiments, the alteration to the magnetic field(s) may be made in response to a magnetic field sensor 472 (FIG. 5A) which detects a change in the ambient magnetic field. The change in the ambient magnetic field may alter the direction of the directional magnetic fields at the magnetometers 160. The alteration in step 1110 may return the direction of the directional magnetic field back to the previous direction (or may produce a different direction.)

It will be recognized that a magnetic field measurement system 140 (FIG. 1) may be configured to adjust the magnetic field(s) for any one of these reasons or any combination of these reasons.

It will be understood that the system can include one or more of the methods described hereinabove with respect to FIGS. 10 and 11 in any combination. The methods, systems, and units described herein may be embodied in many different forms and should not be construed as limited to the embodiments set forth herein.

Accordingly, the methods, systems, and units described herein may take the form of an entirely hardware embodiment, an entirely software embodiment or an embodiment combining software and hardware aspects. The methods described herein can be performed using any type of processor or any combination of processors where each processor performs at least part of the process.

It will be understood that each block of the flowchart illustrations, and combinations of blocks in the flowchart illustrations and methods disclosed herein, can be implemented by computer program instructions. These program instructions may be provided to a processor to produce a machine, such that the instructions, which execute on the processor, create means for implementing the actions specified in the flowchart block or blocks disclosed herein. The computer program instructions may be executed by a processor to cause a series of operational steps to be performed by the processor to produce a computer implemented process. The computer program instructions may also cause at least some of the operational steps to be performed in parallel. Moreover, some of the steps may also be performed across more than one processor, such as might arise in a multi-processor computer system. In addition, one or more processes may also be performed concurrently with other processes, or even in a different sequence than illustrated without departing from the scope or spirit of the invention.

The computer program instructions can be stored on any suitable computer-readable medium including, but not limited to, RAM, ROM, EEPROM, flash memory or other memory technology, CD-ROM, digital versatile disks (“DVD”) or other optical storage, magnetic cassettes, magnetic tape, magnetic disk storage or other magnetic storage devices, or any other medium which can be used to store the desired information and which can be accessed by a computing device.

The above specification provides a description of the invention and its manufacture and use. Since many embodiments of the invention can be made without departing from the spirit and scope of the invention, the invention also resides in the claims hereinafter appended.

What is claimed as new and desired to be protected by Letters Patent of the United States is:

1. A magnetic field measurement system, comprising:
an array of magnetometers, wherein the magnetometers i) are unshielded or ii) comprise shielding so that an ambient magnetic field at the magnetometers is reduced no more than 90% by the shielding;
at least one magnetic field generator with each of the at least one magnetic field generator configured to generate a first magnetic field at one or more of the magnetometers, wherein the generated first magnetic field combines with the ambient magnetic field to produce a directional magnetic field at the one or more of the magnetometers, wherein a direction of the directional magnetic field is selectable using the at least one magnetic field generator; and
a controller coupled to the magnetometers and the at least one magnetic field generator, the controller comprising a processor configured for receiving signals from the magnetometers, observing or measuring a magnetic field from the received signals, and controlling the at least one magnetic field generator to generate the first magnetic field and select the direction of the directional magnetic field.

2. The magnetic field measurement system of claim 1, wherein the at least one magnetic field generator is a single magnetic field generator configured to generate the first magnetic field at each of the magnetometers.

3. The magnetic field measurement system of claim 1, wherein the at least one magnetic field generator comprises a plurality of magnetic field generators.

4. The magnetic field measurement system of claim 1, wherein the at least one magnetic field generator comprises a plurality of magnetic field generators with each magnetic field generator, disposed around, and generating the first magnetic field for, a different one of the magnetometers.

5. The magnetic field measurement system of claim 1, wherein each of one or more pairs of the magnetometers are arranged as a gradiometer.

6. The magnetic field measurement system of claim 5, wherein the at least one magnetic field generator comprises a plurality of magnetic field generators with each magnetic field generator, disposed around, and generating the first magnetic field for, a different one of the magnetometers or gradiometers.

7. The magnetic field measurement system of claim 1, further comprising at least one magnetic field sensor configured for observing the ambient magnetic field, wherein the processor of the controller is coupled to the at least one magnetic field sensor and configured to alter the first magnetic field generated by the at least one magnetic field generator in response to a change in the measured ambient magnetic field.

8. The magnetic field measurement system of claim 1, further comprising at least one position or orientation sensor associated with the magnetometers for sensing changes in position or orientation of the magnetometers, wherein the processor of the controller is coupled to the at least one position or orientation sensor and to alter the first magnetic field generated by the at least one magnetic field generator in response to a change in the position or orientation of the magnetometers.

9. A method of measuring or observing a signal source using the magnetic field measurement system of claim 1, the method comprising:
positioning the array of magnetometers in relation to the signal source;
generating, using the at least one magnetic field generator, the first magnetic field at the magnetometers; and
observing or measuring a magnetic field produced by the signal source using the magnetometers.

10. The method of claim 9, further comprising obtaining an estimate of a direction of the magnetic field produced by the signal source and selecting the first magnetic field to produce the directional magnetic field at the magnetometers in a direction that is within 20 degrees of parallel or antiparallel to the direction of the magnetic field produced by the signal source.

11. The method of claim 9, wherein the magnetic field measurement system comprises a sensor selected from a magnetic field sensor, a position sensor, or an orientation sensor, the method further comprising adjusting the first magnetic field is response to the sensor.

12. A method of targeted observation or measurement of a source of electromagnetic signals, the method comprising:
obtaining an estimate of a direction of a source magnetic field generated by a signal source, wherein the signal source is disposed at a site;
positioning an array of magnetometers in relation to the site of the signal source;
generating a directional magnetic field in a direction that is within 20 degrees of parallel or antiparallel to the direction of the source magnetic field at each of a plurality of the magnetometers in the array; and
analyzing signals generated at the plurality of the magnetometers to observe or measure the source magnetic field generated by the signal source.

13. The method of claim 12, wherein the plurality of magnetometers comprises at least one pair of the magnetometers arranged as a gradiometer.

14. The method of claim 12, wherein generating the directional field comprises using at least one magnetic field generator to generate at least one first magnetic field, wherein the at least one first magnetic field combines with an ambient magnetic field to produce the directional magnetic field at each of the magnetometers, wherein a direction of the directional magnetic field is selectable using the at least one magnetic field generator.

15. The method of claim 14, further comprising receiving signals from a magnetic field sensor observing the ambient magnetic field and adjusting the at least one first magnetic field in response to the signals from the magnetic field sensor.

16. The method of claim 12, further comprising receiving signals from a position or orientation sensor observing a position or orientation of the magnetometers and adjusting the at least one first magnetic field in response to the signals from the position or orientation sensor.

17. A magnetic field measurement system, comprising:
an array of magnetometers; and
a controller coupled to the magnetometers, the controller comprising a processor configured to:
obtain an estimate of a direction of a source magnetic field generated by a signal source, wherein the signal source is disposed at a site;
generate a directional magnetic field in a direction that is within 20 degrees of parallel or antiparallel to the direction of the source magnetic field at each of a plurality of the magnetometers arranged in the array and positioned in relation to the site of the signal source; and
analyze signals generated at each of the magnetometers to observe or measure the source magnetic field generated by the signal source.

18. The magnetic field measurement system of claim 17, further comprising at least one magnetic field generator coupled to the controller, wherein the processor is further configured to, for each of the at least one magnetic field generator, generate a first magnetic field at one or more of the magnetometers, wherein the first magnetic field combines with an ambient magnetic field to produce the directional magnetic field at the one or more of the magnetometers, wherein the direction of the directional magnetic field is selectable using the at least one magnetic field generator.

19. The magnetic field measurement system of claim 18, further comprising a sensor selected from a magnetic field sensor, a position sensor, or an orientation sensor, wherein the processor is further configured to adjust the first magnetic field in response to the sensor.

20. The magnetic field measurement system of claim 17, wherein the magnetometers i) are unshielded or ii) comprise shielding so that an ambient magnetic field at the magnetometers is reduced no more than 90% by the shielding.
